(19) United States
(12) Patent Application Publication
(10) Pub. No.: US 2024/0021412 A1
(43) Pub. Date: Jan. 18, 2024

(54) SUBSTRATE PROCESSING APPARATUS AND SUBSTRATE PROCESSING METHOD

(71) Applicant: SEMES CO., LTD., Chungcheongnam-do (KR)

(72) Inventors: Seong Pyo AHN, Chungcheongnam-do (KR); Yoon Jong JU, Chungcheongnam-do (KR); Hyun Min LIM, Chungcheongnam-do (KR); Min Sung HAN, Chungcheongnam-do (KR); Jae Hoo LEE, Chungcheongnam-do (KR)

(21) Appl. No.: 18/119,882

(22) Filed: Mar. 10, 2023

(30) Foreign Application Priority Data
Jul. 15, 2022 (KR) 10-2022-0087395

(51) Int. Cl. H01J 37/32

(52) U.S. Cl. CPC H01J 37/3244; H01J 37/32422; H01J 37/32082; H01J 2237/3343

(57) ABSTRACT

A substrate processing apparatus includes: a processing chamber including a plasma generating region, a gas mixing region, and a substrate processing region; a first gas supply line supplying a first processing gas to the plasma generating region; a second gas supply line supplying a second processing gas to the gas mixing region; an ion blocker disposed between the plasma generating region and the gas mixing region; and a shower head disposed between the gas mixing region and the substrate processing region, wherein the ion blocker has a first blocker flow path unit connected to the second gas supply line and open to the plasma generating region, so that the second processing gas is supplied to the plasma generating region.

### CROSS-REFERENCE TO RELATED APPLICATION(S)

This application claims the benefit under 35 USC 119(a) of Korean Patent Application No. 10-2022-0087395 filed on Jul. 15, 2022 in the Korean Intellectual Property Office, the entire disclosure of which is incorporated herein by reference for all purposes.

The present disclosure relates to a substrate processing apparatus and a substrate processing method.

Plasma may be used in a process of processing a substrate. For example, plasma may be used for dry cleaning, ashing, or etching processes. Plasma is generated by a very high temperature, a strong electric field or a high-frequency electromagnetic field (an RF Electromagnetic Field). Plasma refers to ionized gaseous matter composed of ions, electrons, or radicals. The dry cleaning process, ashing process, or etching process using plasma is performed when ion or radical particles included in plasma collide with a substrate.

Meanwhile, in a plasma etching process, an etchant (reactive gas or etching gas) for etching a substrate is generated by a mixing process of mixing gas and radicals in a gas mixing region of a processing chamber. However, since the processing gas reacts with radicals only in the gas mixing region, there is a limit to generation efficiency of the etchant.
(Patent Document 1) Republic of Korea Patent Publication No. 10-2021-0024241

### SUMMARY

The present disclosure has been devised to solve the above problems, and an aspect of the present disclosure is to provide a substrate processing apparatus and a substrate processing method for improving generation efficiency of an etchant for processing a substrate.

According to an aspect of the present disclosure, a substrate processing apparatus, includes: a processing chamber including a plasma generating region, a gas mixing region, and a substrate processing region; a first gas supply line supplying a first processing gas to the plasma generating region; a second gas supply line supplying a second processing gas to the gas mixing region; an ion blocker disposed between the plasma generating region and the gas mixing region; and a shower head disposed between the gas mixing region and the substrate processing region, wherein the ion blocker has a first blocker flow path unit connected to the second gas supply line and open to the plasma generating region, so that the second processing gas is supplied to the plasma generating region.

The first blocker flow path unit may include a first blocker channel connected to the second gas supply line and formed inside the ion blocker; and a first blocker hole connected to the first blocker channel and formed to be open to the plasma generating region.

The plurality of the first blocker holes may be disposed to be spaced apart from each other along the first blocker channel.

The ion blocker may have a second blocker flow path unit connected to the second gas supply line and open to the gas mixing region, so that the second processing gas is supplied to the gas mixing region.

The second blocker flow path unit may include a second blocker channel connected to the second gas supply line and formed inside the ion blocker; and a second blocker hole connected to the second blocker channel and formed to be open to the gas mixing region.

The ion blocker may be divided into a first region formed in a central portion and a second region disposed around the first region.

The first blocker flow path unit may be formed in the first region.

The second blocker flow path unit may be formed in the second region.

The ion blocker may have a blocker through-hole connecting the plasma generating region and the gas mixing region formed therein, and the shower head may have a head through-hole connecting the gas mixing region and the substrate processing region formed therein.

The shower head may have a head flow path unit connected to the second gas supply line and open to the gas mixing region, so that the second processing gas is supplied to the gas mixing region.

The head flow path unit may include a head channel connected to the second gas supply line and formed inside the shower head; and a head hole connected to the head channel and formed to be open to the gas mixing region.

According to another aspect of the present disclosure, a substrate processing apparatus may be provided, the substrate processing apparatus including: a processing chamber including a plasma generating region, a gas mixing region, and a substrate processing region; an ion blocker disposed between the plasma generating region and the gas mixing region; a shower head disposed between the gas mixing region and the substrate processing region; a first gas supply line connected to the processing chamber, and supplying a first processing gas to the plasma generating region; a second gas supply line connected to the ion blocker, and supplying a second processing gas to the gas mixing region; and a high-frequency power supply applying a high-frequency voltage to the processing chamber, wherein the ion blocker has a first blocker flow path unit connected to the second gas supply line and open to the plasma generating region, so that the second processing gas is supplied to the plasma generating region.

According to another aspect of the present disclosure, a substrate processing method may be provided, the substrate processing method including: a first gas supply operation of supplying a first processing gas to a plasma generating region in a processing chamber; a second gas supply operation of supplying a second processing gas to the plasma generating region in the processing chamber and a gas mixing region adjacent to the plasma generating region; a plasma generating operation of converting the first processing gas into a plasma state in the plasma generating region; a first reaction operation of generating an etchant by reacting the second processing gas with radicals of the plasma in the plasma generating region; a second reaction operation generating an etchant by reacting the second processing gas with radicals of the plasma supplied from the plasma generating region in the gas mixing region; and a substrate processing operation of processing a substrate with the etchant supplied from the gas mixing region, in a substrate processing region adjacent to the gas mixing region in the processing chamber.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating a substrate processing apparatus according to the prior art.

FIG. 2 is a view illustrating a gas flow in the substrate processing apparatus of FIG. 1.

FIG. 3 is a view illustrating a substrate processing apparatus according to a first embodiment of the present disclosure.

FIG. 4A is a view illustrating a portion of an upper surface of an ion blocker in the substrate processing apparatus of FIG. 3, and FIG. 4B is a view illustrating a portion of a lower surface of an ion blocker in the substrate processing apparatus of FIG. 3.

FIG. 5 is a view illustrating a gas flow in the substrate processing apparatus of FIG. 4A and FIG. 4B.

FIG. 6 is a view illustrating a substrate processing apparatus according to a second embodiment of the present disclosure.

FIG. 7 is a plan view illustrating the ion blocker of FIG. 6.

FIG. 8 is a view illustrating a substrate processing apparatus according to a third embodiment of the present disclosure.

FIG. 9 is a flowchart illustrating a substrate processing method according to an embodiment of the present disclosure.

### DETAILED DESCRIPTION

Hereinafter, preferred embodiments of the present disclosure will be described in detail so that those skilled in the art could easily practice the present disclosure with reference to the accompanying drawings. However, in describing a preferred embodiment of the present disclosure in detail, if it is determined that a detailed description of a related known function or configuration may unnecessarily obscure the subject matter of the present disclosure, the detailed description will be omitted. In addition, the same reference numerals are used throughout the drawings for parts having similar functions and actions. In addition, in the present specification, terms such as ‘upper,’ ‘upper portion,’ ‘upper surface,’ ‘lower,’ ‘lower portion,’ ‘lower surface,’ ‘side surface,’ and the like are based on the drawings, and in practice, it may be different depending on a direction in which the components are placed. In addition, throughout the specification, when a part is said to be ‘connected’ to another part, this is not only when it is ‘directly connected,’ but also when it is ‘indirectly connected’ with other components therebetween. In addition, ‘including’ a certain component means that other components may be further included without excluding other components unless otherwise stated.

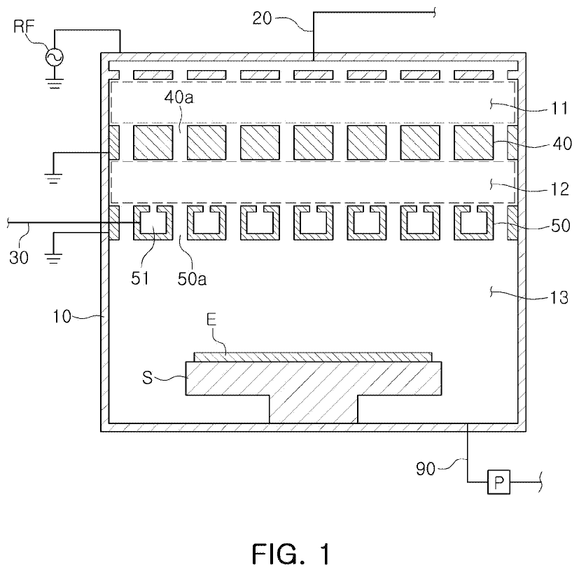

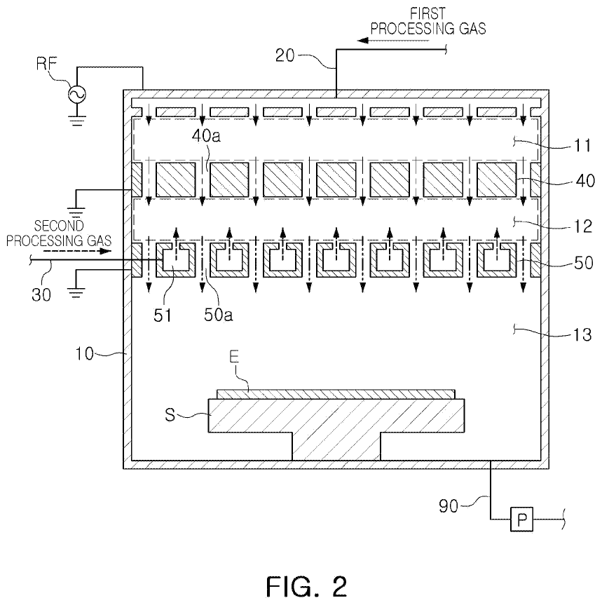

FIG. 1 is a view illustrating a substrate processing apparatus according to the prior art, and FIG. 2 is a view illustrating a gas flow in the substrate processing apparatus of FIG. 1.

Referring to FIGS. 1 and 2, a substrate processing apparatus according to the prior art includes a processing chamber 10, and the processing chamber 10 has an internal space for processing a substrate S. A substrate support E for supporting the substrate S is disposed in the internal space of the processing chamber 10. A gas discharge line 90 is connected to a lower portion of the processing chamber 10, and a pump P is installed in a gas discharge line 90.

Specifically, the processing chamber 10 has a plasma generating region 11, a gas mixing region 12, and a substrate processing region 13 formed therein. The first gas supply line 20 supplies a first processing gas to the plasma generating region 11, and the second gas supply line 30 supplies a second processing gas to the gas mixing region 12. The ion blocker 40 is disposed between the plasma generating region 11 and the gas mixing region 12, and the ion blocker 40 has a blocker through-hole 40a connecting the plasma generating region 11 and the gas mixing region 12, formed therein. The shower head 50 is disposed between the gas mixing region 12 and the substrate processing region 13, and the shower head 50 has a head through-hole 50a connecting the gas mixing region 12 and the substrate processing region 13 formed therein.

The substrate processing apparatus is configured so that only a second processing gas is supplied to the gas mixing region 12. In detail, the shower head 50 includes a head flow path unit 51 to which a second gas supply line 30 is connected. The head flow path unit 51 is formed to be open to the gas mixing region 12 so that the second processing gas is supplied only to the gas mixing region 12. Accordingly, since the second processing gas reacts with plasma radicals only in the gas mixing region 12, there is a limitation in generation efficiency of an etchant.

In order to overcome the limitation of the prior art described above, in the present disclosure, it is configured so that the second processing gas is supplied not only to the gas mixing region but also to the plasma generating region. Accordingly, the second processing gas reacts with radicals of plasma in the plasma generating region as well as in the gas mixing region, thereby improving the generation efficiency of the etchant and increasing selectivity.

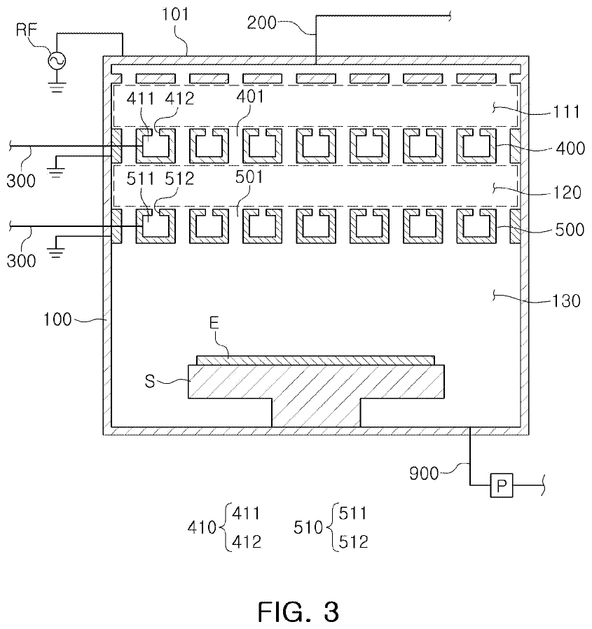

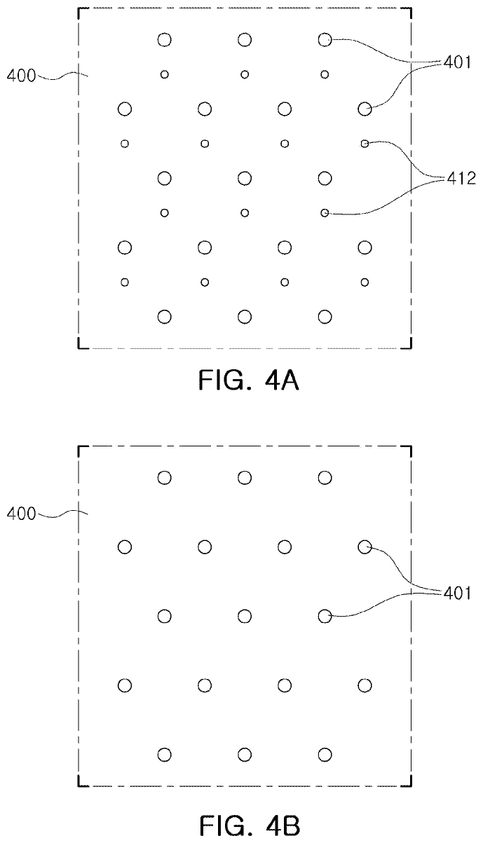

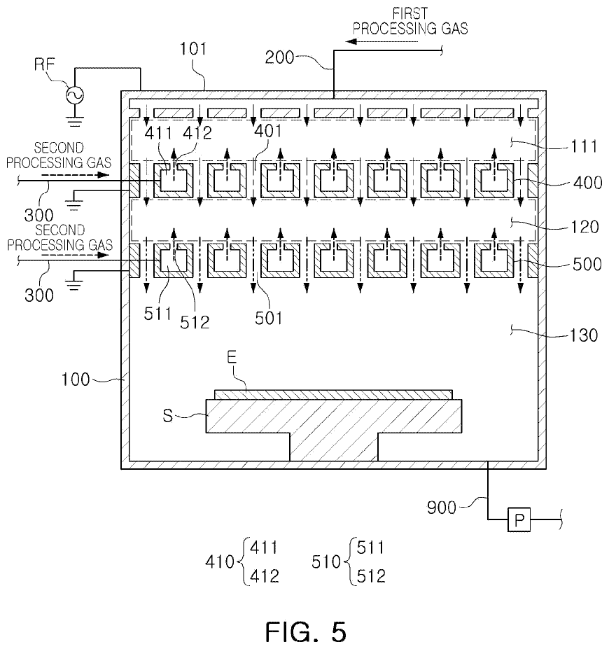

FIG. 3 is a view illustrating a substrate processing apparatus according to a first embodiment of the present disclosure. In addition, FIG. 4A is a view illustrating a portion of an upper surface of an ion blocker in the substrate processing apparatus of FIG. 3, and FIG. 4B is a view illustrating a portion of a lower surface of an ion blocker in the substrate processing apparatus of FIG. 3. In addition, FIG. 5 is a view illustrating a gas flow in the substrate processing apparatus of FIG. 4A and FIG. 4B.

Referring to the drawings, a substrate processing apparatus according to the present disclosure includes a processing chamber 100, a first gas supply line 200, a second gas supply line 300, an ion blocker 400, and a shower head 500. Here, the first gas supply line 200 and the second gas supply line 300 are connected to the processing chamber 100, and the ion blocker 400 and the shower head 500 are disposed in the processing chamber 100.

The processing chamber 100 has an internal space for processing a substrate S. A substrate support E for supporting the substrate S is disposed in the internal space of the processing chamber 100. A gas discharge line 900 is connected to a lower portion of the processing chamber 100, and a pump P is installed in a gas discharge line 900. By-products after processing the substrate S are discharged through the gas discharge line 900, and pressure inside the processing chamber 100 may be controlled by the pump P. The processing chamber 100 has a plasma generating region 110, a gas mixing region 120, and a substrate processing region 130 formed therein. The plasma generating region 110, the gas mixing region 120, and the substrate process region 130 has a structure, sequentially connected from an upper side to a lower side thereof inside the processing chamber 100.

The plasma generating region 110 is a region in which a first processing gas supplied therein is converted into a plasma state. The first processing gas is supplied by a first gas supply line 200 connected to an upper portion 101 of the processing chamber 100. The first processing gas supplied from the first gas supply line 200 is supplied to the plasma generating region 110 via the upper portion 101 of the processing chamber 100. Specifically, the plasma generating region 110 is disposed between the upper portion 101 of the upper processing chamber 100 and the lower ion blocker. The upper portion 101 of the processing chamber 100 serves as an upper electrode to which a high-frequency power supply RF is connected and a high frequency voltage is applied. The ion blocker 400 is connected to a ground electrode and serves as a lower electrode. A high-frequency voltage is applied to the upper portion 101 (upper electrode) of the processing chamber 100 by the high-frequency power supply (RF) and the ion blocker 400 (lower electrode) maintains an electrically grounded state, so that a high-frequency electromagnetic field is formed (strong electric field is applied) in the plasma generating region 110 so that a first processing gas is converted into a plasma state. The first processing gas may be a gas containing fluorine (F) such as HF or NF₃, which is mainly used in an etching or cleaning process.

The gas mixing region 120 is a region in which a second processing gas supplied therein reacts with radicals to generate an etchant (reaction gas or etching gas). The second processing gas is supplied by a second gas supply line 300 connected to the shower head 500. The second processing gas supplied from the second gas supply line 300 is supplied to the gas mixing area 120 via the shower head 500. Among plasma components generated in the plasma generating region 110, radicals pass through the ion blocker 400 and are supplied to the gas mixing region 120.

Specifically, the gas mixing region 120 is disposed below the ion blocker 400. That is, the ion blocker 400 is disposed between the plasma generating region 110 and the gas mixing region 120 to block passage of ions. Specifically, the ion blocker 400 is connected to a ground electrode and grounded, thereby absorbing ions and electrons from plasma components. In the ion blocker 400, a blocker through-hole 401 is formed, and only radicals among plasma components of the plasma generating region 110 pass through the blocker through-hole 401 to the gas mixing region 120. These radicals react with a second processing gas in the gas mixing region 120 to generate an etchant (reaction gas or etching gas). The radical may be a fluorine radical (F—), and the second processing gas may be NH₃ or a gas mixture of NH₃ and H₂. In addition, the etchant may be NH₄F or a gas mixture of NH₄F and HF for etching a polysilicon film and silicon oxide of the substrate S in the substrate processing region 130.

The substrate process region 130 is a region in which a surface of the substrate S is processed by an etchant. Specifically, the substrate processing area 130 is disposed below a shower head 500. That is, the shower head 500 is disposed between the gas mixing region 120 and the substrate processing region 130. A head through-hole 501 is formed in the shower head 500, and an etchant generated in the gas mixing region 120 passes through the head through-hole 501 and is supplied toward the substrate processing region 130.

Meanwhile, the ion blocker 400 has a first blocker flow path unit 410 so that a second processing gas is supplied to the plasma generating region 110. The second processing gas is supplied through a second gas supply line 300 connected to the ion blocker 400. The first blocker flow path unit 410 is connected to the second gas supply line 300 and has a structure open to the plasma generating region 110.

The first blocker flow path unit 410 includes a first blocker channel 411 and a first blocker hole 412. The first blocker channel 411 is connected to the second gas supply line 300 and is formed inside the ion blocker 400. The first blocker channel 411 has a structure formed in a long or large space inside the ion blocker 400. As an example, the first blocker channel 411 may have various structures such as a plurality of interconnected concentric circles.

The first blocker hole 412 is connected to the first blocker channel 411 and is formed to be open to the plasma generating region 110. A plurality of first blocker holes 412 may be formed to be spaced apart from each other along the first blocker channel 411. Furthermore, the plurality of first blocker holes 412 may be disposed around the blocker through-hole 401.

A second processing gas supplied through a second gas supply line 300 is supplied to the upper plasma generating region 110 through the first blocker channel 411 and the first blocker hole 412 configured as described above. That is, the second processing gas supplied through the second gas supply line 300 is introduced into the first blocker channel 411, and then supplied to the plasma generating region 110 through the first blocker hole 412.

In the present disclosure, the second processing gas is supplied to the plasma generating region 110 through the first blocker flow path unit 410 of the ion blocker 400, so that the second processing gas may react with plasma radicals not only in the gas mixing region 110 but also in the gas mixing region 120. Accordingly, in the present disclosure, by increasing mixing efficiency of the second processing gas and the radicals to improve generation efficiency of the etchant, selectivity in the etching process may be increased.

The shower head 500 is disposed between the gas mixing region 120 and the substrate processing region 130. The shower head 500 has a head flow path unit 510 so that a second processing gas is supplied to the gas mixing region 120. The second processing gas is supplied through the second gas supply line 300 connected to the shower head 500. The head flow path unit 510 is connected to the second gas supply line 300 and has a structure open to the plasma generating region 110.

Specifically, the head flow path unit 510 includes a head channel 511 and a head hole 512.

The head channel 511 is connected to a second gas supply line 300 and is formed inside the shower head 500. The head channel 511 takes a structure formed in a long or large space inside the shower head 500. As an example, the head channel 511 may take a variety of structures, such as a plurality of interconnected concentric circles.

The head hole 512 is connected to the head channel 511 and is formed to be open to the gas mixing region 120. A plurality of head holes 512 may be formed spaced apart from each other. Furthermore, the plurality of head holes 512 may be disposed around the head through-hole 501.

The second processing gas supplied through the second gas supply line 300 is supplied to the gas mixing region 120 through the head channel 511 and the head hole 512 configured as described above. That is, the second processing gas supplied through the second gas supply line 300 is introduced into the head channel 511, and then supplied to the gas mixing region 120 through the head hole 512.

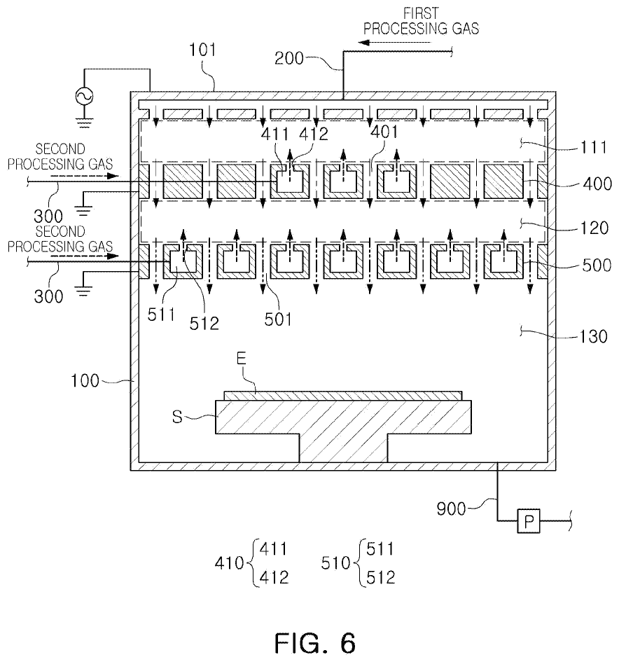

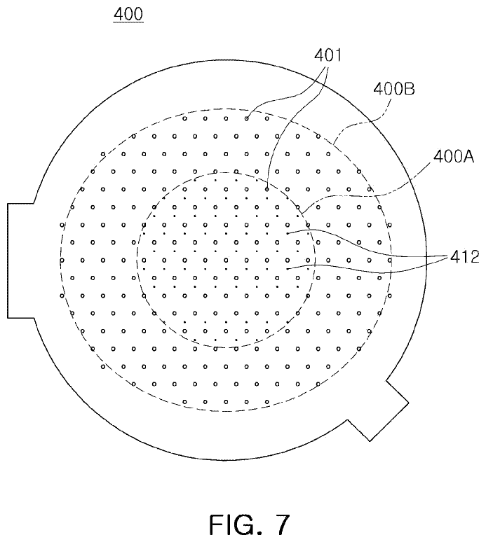

FIG. 6 is a view illustrating a substrate processing apparatus according to a second embodiment of the present disclosure, and FIG. 7 is a plan view illustrating the ion blocker of FIG. 6.

Referring to FIG. 6, the ion blocker 400 may be divided into a first region 400A and a second region 400B. The first region 400A is formed in a central portion of the ion blocker 400. When the ion blocker 400 has a disk-like shape, each of the first region 400A and the second region 400B may be a circular region. Furthermore, although not illustrated in the drawings, the ion blocker 400 may be divided into two or more regions.

An etchant flows on a substrate S. Specifically, the etchant descending from an upper side of the substrate S reaches the substrate S and then flows toward an edge thereof. Subsequently, the etchant has a flow leaving the substrate S and descending toward a gas discharge line 900 on a lower side thereof. Therefore, an etching rate of the substrate S may be higher in an edge portion of the substrate S than that in a central portion of the substrate S.

In order to make the etching rate of the substrate S uniform, a first blocker flow path unit 410 may be formed in a first region 400A formed in a central portion of the ion blocker 400. The second processing gas may be supplied to the plasma generating region 110 through the first blocker flow path unit 410 formed in the first region 400A. Accordingly, since a large amount of etchant is supplied to the central portion of the substrate S corresponding to the first region 400A, the etching rate of the substrate S may be made uniform.

Furthermore, among the components of the substrate processing apparatus according to the second embodiment illustrated in FIGS. 6 and 7, the same components as those of the substrate processing apparatus according to the first embodiment illustrated in FIGS. 3 to 5 have already been described above, so detailed description will be omitted.

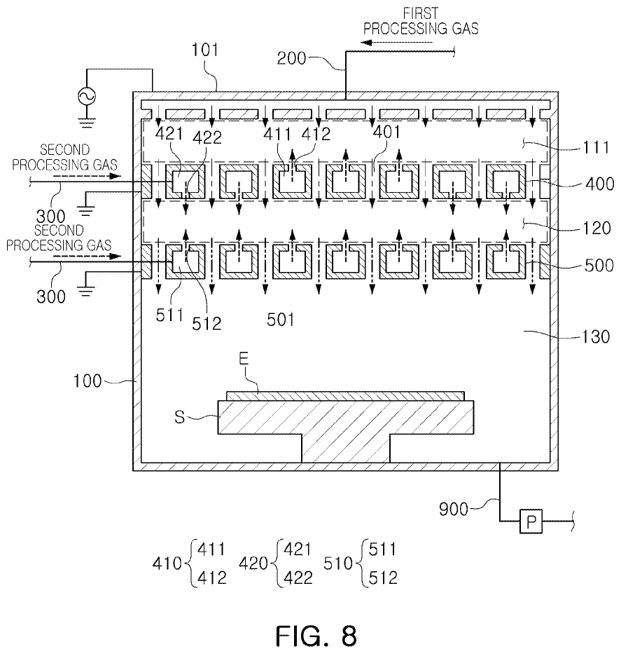

FIG. 8 is a view illustrating a substrate processing apparatus according to a third embodiment of the present disclosure.

Referring to FIG. 8, an ion blocker 400 may have a second blocker flow path unit formed therein, so that a second processing gas is supplied to the gas mixing region 120. The second processing gas is supplied through a second gas supply line 300 connected to the ion blocker 400. The second blocker flow path unit 420 is connected to the second gas supply line 300 and has a structure, open to the gas mixing region 120.

The ion blocker 400 may have a second blocker flow path unit 420 formed therein so that a second processing gas is supplied to the gas mixing region 120. The second processing gas is supplied through a second gas supply line 300 connected to the ion blocker 400. The second blocker flow path unit 420 is connected to the second gas supply line 300 and has a structure, open to the gas mixing region 120.

Specifically, the second blocker flow path unit 420 includes a second blocker channel 421 and a second blocker hole 422.

The second blocker channel 421 is connected to a second gas supply line 300 and is formed inside the ion blocker 400. The second blocker channel 421 has a structure formed in a long or large space inside the ion blocker 400. As an example, the second blocker channel 421 may have various structures such as a plurality of interconnected concentric circles.

The second blocker hole 422 is connected to the second blocker channel 421 and is formed to be open to the lower gas mixing region 120. A plurality of second blocker holes 422 may be formed to be spaced apart from each other. Furthermore, a plurality of second blocker holes 422 may be disposed around the blocker through-hole 401.

The second processing gas supplied through the second gas supply line 300 is supplied to the gas mixing region 120 through the second blocker hole 422 configured as described above. That is, the second processing gas supplied through the second gas supply line 300 is introduced into the second blocker channel 421, and then supplied to the lower gas mixing region 120 through the second blocker hole 422. Accordingly, mixing efficiency of the second processing gas and radicals in the gas mixing region 120 may be increased.

More specifically, the second blocker flow path unit 420 may be formed in a second region 400B of the ion blocker 400. The second region 400B is a region disposed around the first region 400A. As described above, by the second blocker flow path unit 420 formed in the second region 400B, in a portion of the gas mixing region 120, corresponding to an edge portion of the ion blocker 400, mixing efficiency of the second processing gas and radicals may be increased.

Furthermore, among the components of the substrate processing apparatus according to the third embodiment illustrated in FIG. 8, the same components as those of the substrate processing apparatus according to the other embodiments illustrated in FIGS. 3 to 7 have already been described above, so detailed description will be omitted.

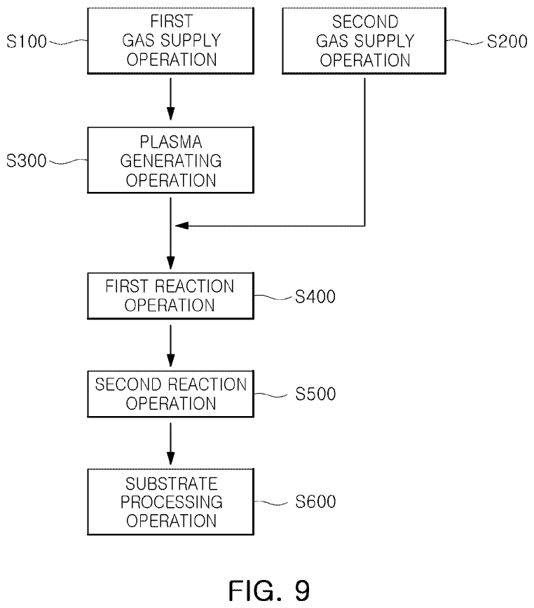

FIG. 9 is a flowchart illustrating a substrate processing method according to an embodiment of the present disclosure.

Referring to FIG. 9, the substrate processing method according to the present disclosure includes a first gas supply operation (S100), a second gas supply operation (S200), a plasma generating operation (S300), a first reaction operation (S400), a second reaction operation (S500), and a substrate processing operation (S600).

First, the first gas supply operation (S100) is an operation of supplying a first processing gas to the plasma generating region 110 in a processing chamber 100.

The second gas supply operation (S200) is an operation of supplying a second processing gas to the plasma generating region 110 and the gas mixing region 120 in the processing chamber 100. That is, in the second gas supply operation (S200), the second processing gas is supplied to the gas mixing region 120, and in addition thereto, the second processing gas is supplied to the plasma generating region 110, which is a previous region of the gas mixing region 120.

Next, the plasma generating operation (S300) is an operation of converting the first processing gas into a plasma state in the plasma generating region 110. That is, the first processing gas supplied to the plasma generating region 110 is converted into a plasma state including radicals by a high-frequency voltage in the plasma generating operation (S300).

Thereafter, the first reaction operation (S400) proceeds. The first reaction step (S400) is an operation of generating an etchant by reacting a second processing gas with plasma radicals in the plasma generating region 110.

The second processing gas is supplied not only to the gas mixing region 120 but also to the plasma generating region 110 in the second gas supply operation (S200). In the first reaction operation (S400), the second processing gas supplied to the plasma generating region 110 reacts with plasma radicals to generate an etchant.

Next, the second reaction operation (S500) proceeds. The second reaction operation (S500) is an operation in which the second processing gas in the gas mixing region 120 reacts with plasma radicals supplied from the plasma generating region 110 to generate an etchant.

Finally, the substrate processing operation (S600) proceeds. The substrate processing operation (S600) is an operation of processing a substrate S with the etchant supplied from the gas mixing region 120 in the substrate processing region 130 adjacent to the gas mixing region 120 in the processing chamber 100.

In the present disclosure configured as described above, before being performed in the gas mixing region 120, which is the second reaction operation (S500), the reaction of the second processing gas to the radicals of the plasma is performed in the gas generating region 110, which is the first operation (S400). Therefore, in the present disclosure, by increasing the generation efficiency of the etchant, selectivity in the etching process may be improved.

As set forth above, according to the present disclosure, the present disclosure is configured to supply a second processing gas not only to a gas mixing region but also to a plasma generating region, thereby improving generation efficiency of an etchant and increasing selectivity.

While exemplary embodiments have been shown and described above, it will be apparent to those skilled in the art that modifications and variations could be made without departing from the scope of the present invention as defined by the appended claims.

### DESCRIPTION OF REFERENCE NUMERALS

100: PROCESSING CHAMBER
101: UPPER PORTION OF PROCESSING CHAMBER
110: PLASMA GENERATING REGION
120: GAS MIXING REGION
130: SUBSTRATE PROCESS REGION
200: FIRST GAS SUPPLY LINE
300: SECOND GAS SUPPLY LINE
400: ION BLOCKER
400A: FIRST REGION
400B: SECOND REGION
401: BLOCKER THROUGH-HOLE
410: FIRST BLOCKER FLOW PATH UNIT
411: FIRST BLOCKER CHANNEL
412: FIRST BLOCKER HOLE
420: SECOND BLOCKER FLOW PATH UNIT
421: SECOND BLOCKER CHANNEL
422: SECOND BLOCKER HOLE
500: SHOWER HEAD
501: HEAD THROUGH-HOLE
510: HEAD FLOW PATH UNIT
511: HEAD CHANNEL
512: HEAD HOLE
S: SUBSTRATE
E: SUBSTRATE SUPPORT
RF: HIGH-FREQUENCY POWER
P: PUMP

What is claimed is:

1. A substrate processing apparatus, comprising:
a processing chamber including a plasma generating region, a gas mixing region, and a substrate processing region;
a first gas supply line supplying a first processing gas to the plasma generating region;
a second gas supply line supplying a second processing gas to the gas mixing region;
an ion blocker disposed between the plasma generating region and the gas mixing region; and
a shower head disposed between the gas mixing region and the substrate processing region,
wherein the ion blocker has a first blocker flow path unit connected to the second gas supply line and open to the plasma generating region, so that the second processing gas is supplied to the plasma generating region.

2. The substrate processing apparatus of claim 1, wherein the first blocker flow path unit comprises,
a first blocker channel connected to the second gas supply line and formed inside the ion blocker; and
a first blocker hole connected to the first blocker channel and formed to be open to the plasma generating region.

3. The substrate processing apparatus of claim 2, wherein the plurality of first blocker holes are disposed to be spaced apart from each other along the first blocker channel.

4. The substrate processing apparatus of claim 1, wherein the ion blocker has a second blocker flow path unit connected to the second gas supply line and open to the gas mixing region, so that the second processing gas is supplied to the gas mixing region.

5. The substrate processing apparatus of claim 4, wherein the second blocker flow path unit comprises
a second blocker channel connected to the second gas supply line and formed inside the ion blocker; and
a second blocker hole connected to the second blocker channel and formed to be open to the gas mixing region.

6. The substrate processing apparatus of claim 1, wherein the ion blocker is divided into a first region formed in a central portion and a second region disposed around the first region.

7. The substrate processing apparatus of claim 6, wherein the first blocker flow path unit is formed in the first region.

8. The substrate processing apparatus of claim 7, wherein the ion blocker has a second blocker flow path unit connected to the second gas supply line and open to the gas mixing region, so that the second processing gas is supplied to the gas mixing region,
wherein the second blocker flow path unit is formed in the second region.

9. The substrate processing apparatus of claim 1, wherein the ion blocker has a blocker through-hole connecting the plasma generating region and the gas mixing region formed therein,
wherein the shower head has a head through-hole connecting the gas mixing region and the substrate process region formed therein.

10. The substrate processing apparatus of claim 1, wherein the shower head has a head flow path unit connected to the second gas supply line and open to the gas mixing region, so that the second processing gas is supplied to the gas mixing region.

11. The substrate processing apparatus of claim 10, wherein the head flow path unit comprises
a head channel connected to the second gas supply line and formed inside the shower head; and
a head hole connected to the head channel and formed to be open to the gas mixing region.

12. A substrate processing apparatus, comprising:
a processing chamber including a plasma generating region, a gas mixing region, and a substrate processing region;
an ion blocker disposed between the plasma generating region and the gas mixing region;
a shower head disposed between the gas mixing region and the substrate processing region;
a first gas supply line connected to the processing chamber, and supplying a first processing gas to the plasma generating region;
a second gas supply line connected to the ion blocker, and supplying a second processing gas to the gas mixing region; and
a high-frequency power supply applying a high-frequency voltage to the processing chamber,
wherein the ion blocker has a first blocker flow path unit connected to the second gas supply line and open to the plasma generating region, so that the second processing gas is supplied to the plasma generating region.

13. The substrate processing apparatus of claim 12, wherein the first blocker flow path unit comprises
a first blocker channel connected to the second gas supply line and formed inside the ion blocker; and
a first blocker hole connected to the first blocker channel and formed to be open to the plasma generating region.

14. The substrate processing apparatus of claim 13, wherein the plurality of first blocker holes are disposed to be spaced apart from each other along the first blocker channel.

15. The substrate processing apparatus of claim 12, wherein the ion blocker has a second blocker flow path unit connected to the second gas supply line and open to the gas mixing region, so that the second processing gas is supplied to the gas mixing region.

16. The substrate processing apparatus of claim 15, wherein the second blocker flow path unit comprises
a second blocker channel connected to the second gas supply line and formed inside the ion blocker; and
a second blocker hole connected to the second blocker channel and formed to be open to the gas mixing region.

17. The substrate processing apparatus of claim 12, wherein the ion blocker is divided into a first region formed in a central portion, and a second region disposed around the first region.

18. The substrate processing apparatus of claim 17, wherein the first blocker flow path unit is formed in the first region.

19. The substrate processing apparatus of claim 18, wherein the ion blocker has a second blocker flow path unit connected to the second gas supply line and open to the gas mixing region, so that the second processing gas is supplied to the gas mixing region.

20. A substrate processing method, comprising:
a first gas supply operation of supplying a first processing gas to a plasma generating region in a processing chamber;
a second gas supply operation of supplying a second processing gas to the plasma generating region in the processing chamber and a gas mixing region adjacent to the plasma generating region;
a plasma generating operation of converting the first processing gas into a plasma state in the plasma generating region;
a first reaction operation of generating an etchant by reacting the second processing gas with radicals of the plasma in the plasma generating region;
a second reaction operation of generating an etchant by reacting the second processing gas with radicals of the plasma supplied from the plasma generating region in the gas mixing region; and
a substrate processing operation of processing a substrate with the etchant supplied from the gas mixing region in a substrate processing region, adjacent to the gas mixing region in the processing chamber.
